(19) United States
(12) Patent Application Publication
(10) Pub. No.: US 2025/0081611 A1
(43) Pub. Date: Mar. 6, 2025

(54) DISPLAY PANEL AND METHOD OF MANUFACTURING A DISPLAY PANEL

(71) Applicants: Hefei BOE Display Technology Co., Ltd., Hefei, Anhui (CN); BOE TECHNOLOGY GROUP CO., LTD., Beijing (CN)

(72) Inventors: Chao LI, Beijing (CN); Liangwei ZHANG, Beijing (CN); Chunxu ZHANG, Beijing (CN); Liang CHEN, Beijing (CN); Wentao LU, Beijing (CN); Wei ZHANG, Beijing (CN); Hui LI, Beijing (CN)

(21) Appl. No.: 18/579,476

(22) PCT Filed: Sep. 23, 2022
(86) PCT No.: PCT/CN2022/121070

§ 371 Date: Jan. 15, 2024

(51) Int. Cl. H01L 27/12; G02F 1/1362; G02F 1/1368

(52) U.S. Cl. CPC H10D 86/60; G02F 1/136286; G02F 1/1368; H10D 86/0231; H10D 86/451; H10D 86/441

(57) ABSTRACT

The present application discloses a display panel and a method of manufacturing a display panel. The display panel comprises a substrate and a signal line arranged on the substrate, wherein the substrate comprises at least one display area, each display area comprises a plurality of pixel areas and a spacing area located between any two adjacent pixel areas of the plurality of pixel areas, the signal line is located within the spacing area, wherein the display panel further comprises an organic film layer, the organic film layer is arranged on a side of the signal line away from the substrate, and an orthographic projection of the organic film layer on the substrate covers an orthographic projection of the signal line on the substrate.

### FIELD

The present application relates to the field of display technology, and particularly relates to a display panel and a method of manufacturing a display panel.

### BACKGROUND

In common LCD display panels, especially large-sized panels, various metal wires such as gate lines and data lines are arranged in the array substrate. These metal wires may form edge electric fields that affect the deflection of the liquid crystal, leading to light leakage problem. To solve this problem, a black mask can be set in the position corresponding to these metal wires in the color film substrate opposite to the array substrate to block light leakage. However, in order to achieve a high degree of blocking light leakage, it is necessary for the black mask to have a certain width, which in related technologies can affect the transmittance of the display panel.

### SUMMARY

According to an aspect of the present application, a display panel is provided, comprising a substrate and a signal line arranged on the substrate, wherein the substrate comprises at least one display area, each display area comprises a plurality of pixel areas and a spacing area located between any two adjacent pixel areas of the plurality of pixel areas, the signal line is located within the spacing area. The display panel further comprises an organic film layer, the organic film layer is arranged on a side of the signal line away from the substrate, and an orthographic projection of the organic film layer on the substrate covers an orthographic projection of the signal line on the substrate.

In some embodiments, the organic film layer comprises a top area and a side surface, the top area is located on a side of the organic film layer away from the signal line, and the side surface is located between the top area and the signal line, wherein an inclination angle of the side surface relative to a plane where the substrate is located is greater than or equal to 15°. In some more specific embodiments, the inclination angle of the side surface relative to a plane where the substrate is located is greater than or equal to 20°.

In some embodiments, the organic film layer extends from the spacing area to the pixel area, wherein the organic film layer comprises a first organic film portion and a second organic film portion, the first organic film portion is located in the spacing area, and the second organic film portion is located in the pixel area, wherein an average thickness of the first organic film portion is greater than an average thickness of the second organic film portion.

In some embodiments, the average thickness of the first organic film portion is greater than or equal to 15000 Å.

In some embodiments, the average thickness of the second organic film portion is less than or equal to 8000 Å.

In some embodiments, the display panel further comprises a common electrode layer, the common electrode layer comprising a plurality of parallel and spaced strip-shaped common electrodes, wherein some of the plurality of strip-shaped common electrodes are arranged in the spacing area, and the organic film layer is located between the strip-shaped common electrodes that are arranged in the spacing area and the signal line.

In some embodiments, the at least one display area comprises a plurality of display areas, the substrate further comprises a plurality of non-display areas, each of the plurality of non-display areas surrounds a corresponding display area of the plurality of display areas, the substrate further comprises a cutting area located between any two adjacent non-display areas of the plurality of non-display areas, wherein the organic film layer extends from the display area to the non-display area and the cutting area.

In some embodiments, the organic film layer comprises a first organic film portion, a second organic film portion, a third organic film portion and a fourth organic film portion, the first organic film portion is located in the spacing area, the second organic film portion is located in the pixel area, the third organic film portion is located in the cutting area, the fourth organic film portion is located in the non-display area, wherein an average thickness of the third organic film portion is greater than or equal to an average thickness of the first organic film portion, and the average thickness of the third organic film portion is greater than an average thickness of at least one of the second organic film portion and the fourth organic film portion.

In some embodiments, the fourth organic film portion comprises a groove portion and an edge portion located on both sides of the groove portion, an average thickness of the groove portion is less than an average thickness of the edge portion, wherein the display panel further comprises a sealant, which is located in the groove portion.

In some embodiments, the display panel further comprises a photo space, wherein the photo space is located on a side of the organic film layer away from the substrate.

In some embodiments, the organic film layer comprises a via hole, the via hole comprises a first opening, a second opening, and an inner wall located between the first opening and the second opening, the inner wall comprises a first inner wall slope gradient zone, a second inner wall slope gradient zone, and an inner wall slope stability zone between the first inner wall slope gradient zone and the second inner wall slope gradient zone, wherein an inclination angle of the inner wall slop stability zone relative to the plane where the substrate is located is less than or equal to 20°. In some more specific embodiments, the inclination angle of the inner wall slop stability zone relative to the plane where the substrate is located is less than or equal to 15°.

According to another aspect of the present application, a method of manufacturing a display panel is provided. The method comprises: providing a substrate, wherein the substrate comprises at least one display area, each display area comprises a plurality of pixel areas and a spacing area located between any two adjacent pixel areas of the plurality of pixel areas; forming a signal line on the substrate, wherein the signal line is located within the spacing area; forming an organic film layer on a side of the signal line away from the substrate, wherein an orthographic projection of the organic film layer on the substrate covers an orthographic projection of the signal line on the substrate.

In some embodiments, forming an organic film layer on a side of the signal line away from the substrate comprises: forming an organic material layer on a side of the signal line way from the substrate; exposing and developing the organic material layer using a halftone mask so as to form the organic material layer as an organic material pattern layer, wherein the organic material pattern layer comprises an organic material fully reserved area and an organic material partially reserved area, the organic material fully reserved area is located in the spacing area, the organic material partially reserved area is located in the pixel area, wherein a thickness of the organic material fully reserved area is greater than a thickness of the organic material partially reserved area; curing the organic material pattern layer so as to obtain the organic film layer.

In some embodiments, curing the organic material pattern layer so as to obtain the organic film layer comprises: heating at a first temperature and irradiating the organic material pattern layer with ultraviolet light with a first irradiance to obtain a pre-cured layer, wherein the first temperature is within a range of 120° C. to 140° C., and the first irradiance is within a range of 700 mw/cm²-1000 mw/cm²; and heating the pre-cured layer at a second temperature so as to obtain the organic film layer, wherein the second temperature is within a range of 230° C. to 250° C.

In some embodiments, the at least one display area comprises a plurality of display areas, the substrate further comprises a plurality of non-display areas, each of the plurality of non-display areas surrounds a corresponding display area of the plurality of display areas, the substrate further comprises a cutting area located between any two adjacent non-display areas of the plurality of non-display areas, wherein in the step of exposing and developing the organic material layer using a halftone mask so as to form the organic material layer as an organic material pattern layer, the organic material partially reserved area comprises a first organic material partially reserved area and a second organic material partially reserved area, wherein the organic material fully reserved area is located in the spacing area and the cutting area, the first organic material partially reserved area is located in the non-display area, and the second organic material partially reserved area is located in the pixel area.

In some embodiments, the first organic material partially reserved area comprises a groove portion and an edge portion located on both sides of the groove portion, an average thickness of the groove portion is less than an average thickness of the edge portion, wherein the method further comprises: providing a sealant in the groove portion.

In some embodiments, the organic film layer comprises a via hole, and forming an organic film layer on a side of the signal line away from the substrate comprises: forming an organic material layer on a side of the signal line way from the substrate; exposing and developing the organic material layer using a halftone mask so as to form the organic material layer as an organic material pattern layer, wherein the organic material pattern layer comprises a via hole pattern, which comprises a first opening, a second opening, and an inner wall pattern located between the first opening and the second opening, the first opening is located on a surface of the organic material pattern layer away from the substrate, the second opening is located on a surface of the organic pattern layer near the substrate, the inner wall pattern comprises a first climbing zone, a second climbing zone, and a step portion located between the first climbing zone and the second climbing zone, the step portion is parallel to the first opening and the second opening; curing the organic material pattern layer so as to obtain the organic film layer.

In some embodiments, a ratio of a distance from the step portion to the first opening to a distance from the step portion to the second opening is within a range of 90%-110%.

### DETAILED DESCRIPTION OF THE DRAWINGS

In order to provide a clearer description of the technical solution in the embodiments of the present application, the accompanying drawings required in the embodiments will be briefly introduced below. Obviously, the accompanying drawings in the following description are only some embodiments of the present application. For those ordinary skilled in the art, other drawings can be obtained based on these drawings without inventive efforts. In the accompanying drawings, identical or similar components can be represented by identical or similar patterns or symbols. It should be understood that unless explicitly described, the patterns or symbols in the accompanying drawings are only used to distinguish the components, but not to limit the shape of the components. In the accompanying drawings of the present application:

FIG. 1 schematically illustrates a partial top view of a display panel according to an embodiment of the present application;

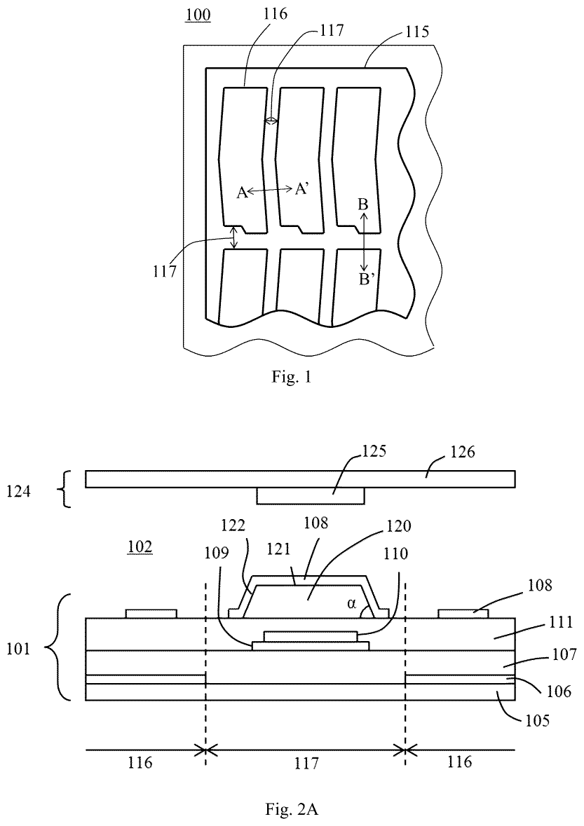

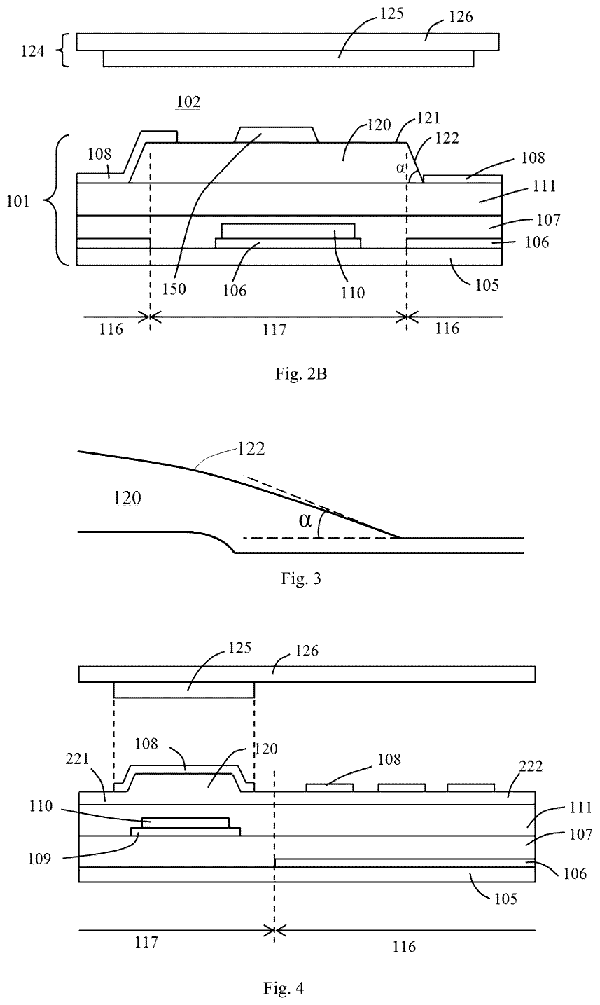

FIG. 2A schematically illustrates a partial cross-sectional view of a display panel according to an embodiment of the present application;

FIG. 2B schematically illustrates a partial cross-sectional view of a display panel according to an embodiment of the present application;

FIG. 3 schematically illustrates an inclination angle of a side surface of an organic film layer relative to the plane where the substrate is located according to an embodiment of the present application;

FIG. 4 schematically illustrates a partial cross-sectional view of a display panel according to an embodiment of the present application;

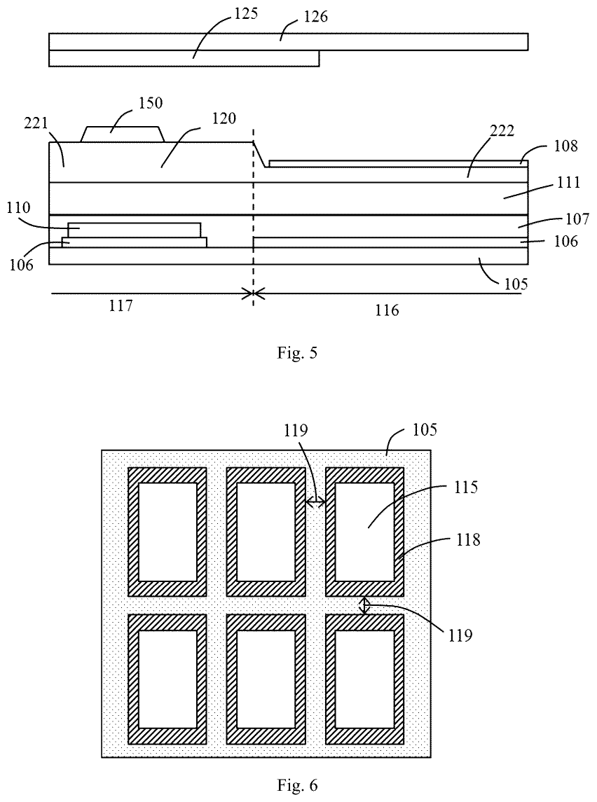

FIG. 5 schematically illustrates a partial cross-sectional view of a display panel according to an embodiment of the present application;

FIG. 6 schematically illustrates a top view of a display panel according to an embodiment of the present application;

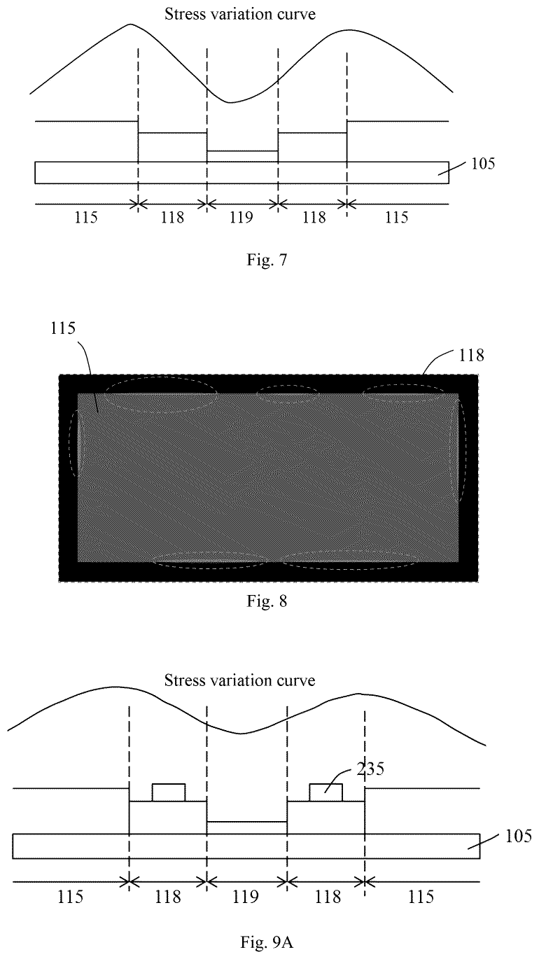

FIG. 7 schematically shows a stress variation curve of the relevant display panel;

FIG. 8 schematically illustrates the edge light leakage phenomenon of the relevant display panel;

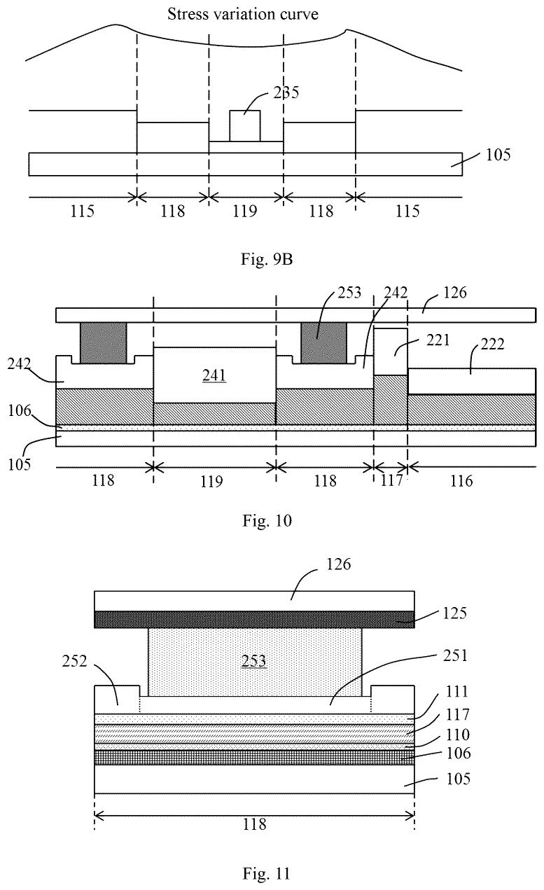

FIG. 9A and FIG. 9B schematically show the stress variation curves of the relevant display panel with segment difference improvement layer;

FIG. 10 schematically illustrates a partial cross-sectional view of a display panel according to an embodiment of the present application;

FIG. 11 schematically illustrates a partial cross-sectional view of a display panel according to an embodiment of the present application;

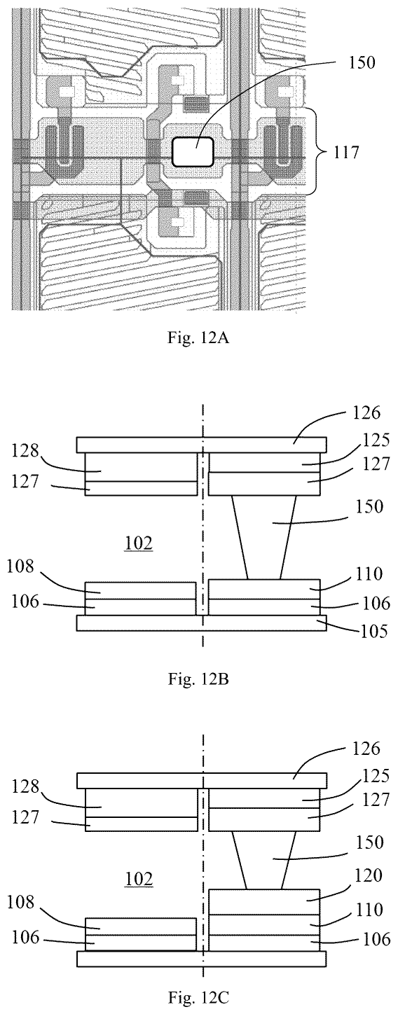

FIG. 12A schematically illustrates a partial top view of a display panel according to an embodiment of the present application;

FIG. 12B schematically illustrates a partial cross-sectional view of the relevant display panel;

FIG. 12C schematically illustrates a partial cross-sectional view of a display panel according to an embodiment of the present application;

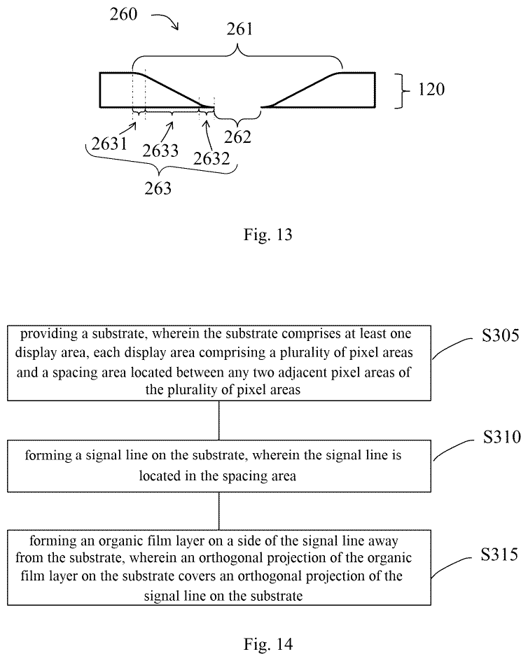

FIG. 13 schematically illustrates a cross-sectional view of a via hole in the organic film layer of the display panel according to an embodiment of the present application;

FIG. 14 schematically illustrates the flowchart of a method of manufacturing a display panel according to an embodiment of the present application;

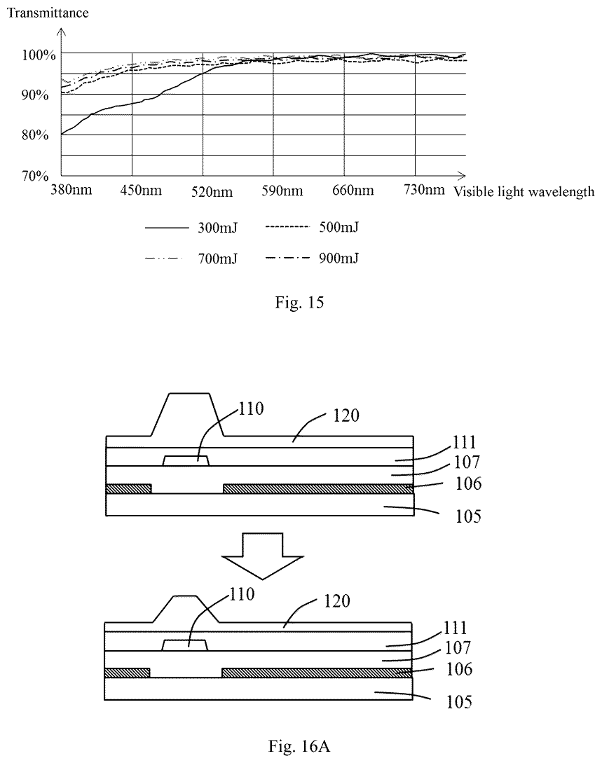

FIG. 15 schematically illustrates the transmittance of the organic film layer to visible light after being irradiated with different doses of ultraviolet light;

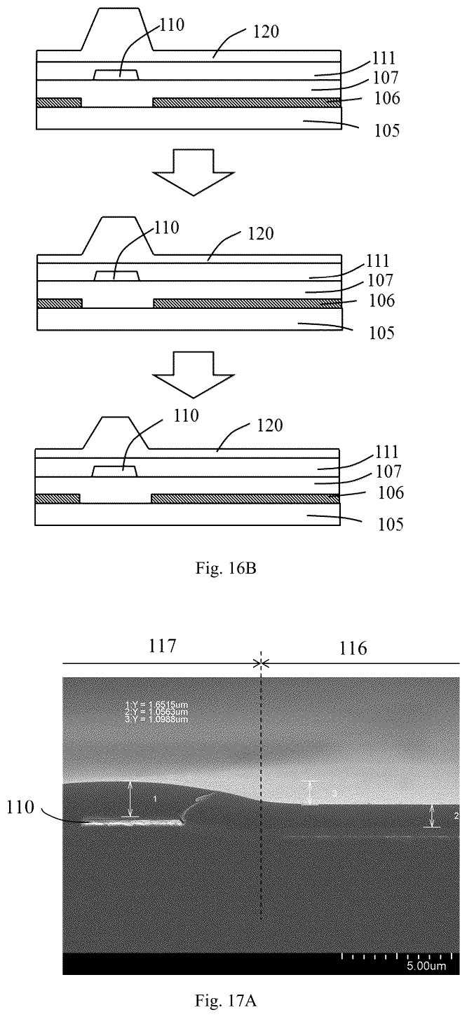

FIG. 16A schematically illustrates the morphology of each stage of the organic film layer in the relevant process of forming the relevant organic film layer;

FIG. 16B schematically illustrates the morphology of each stage of the organic film layer in the process of forming an organic film layer in the method of manufacturing a display panel according to the embodiment of the present application;

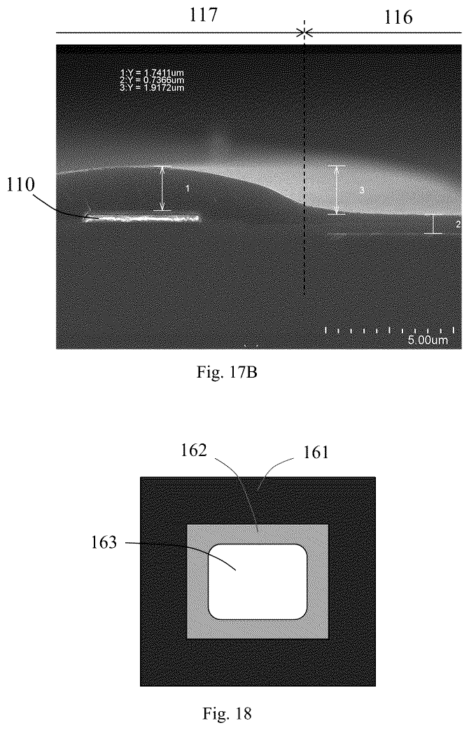

FIG. 17A schematically illustrates the segment difference image of the organic film layer obtained using relevant methods;

FIG. 17B schematically illustrates the segment difference image of the organic film layer obtained using the method of manufacturing a display panel according to the embodiment of the present application;

FIG. 18 schematically illustrates a top view of a halftone mask used to form a via hole in the method of manufacturing a display panel according to the embodiment of the present application;

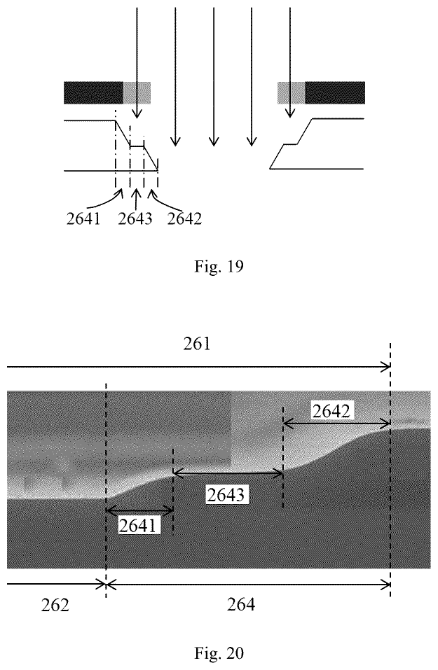

FIG. 19 schematically illustrates a cross-sectional view of a via hole pattern obtained when exposing an organic material layer using a halftone mask;

FIG. 20 schematically illustrates a cross-sectional image of the via hole pattern.

### EMBODIMENTS

Next, the technical solutions in the embodiments of the present application will be described in conjunction with the accompanying drawings in the embodiments of the present application. Apparently, the described embodiments are merely a part of rather than all of the embodiments of the present application. Based on the described embodiments, all other embodiments obtained by those ordinary skilled in the art without inventive efforts fall within the protection scope of the present application.

According to an aspect of the present application, a display panel is provided. FIG. 1 schematically illustrates a partial top view of a display panel according to an embodiment of the present application. FIG. 2A schematically illustrates a partial cross-sectional view of a display panel according to an embodiment of the present application. Specifically, FIG. 2A is a cross-sectional view of the display panel according to the embodiment of the present application along the A-A′ line in FIG. 1. FIG. 2B schematically illustrates another partial cross-sectional view of a display panel according to an embodiment of the present application. Specifically, FIG. 2B is a cross-sectional view of the display panel according to the embodiment of the present application along the B-B′ line in FIG. 1. As shown in FIG. 1 to FIG. 2B, the display panel 100 comprises a substrate 105 and a signal line 110 arranged on the substrate. The substrate 105 comprises at least one display area 115. The display area refers to the area in the display panel for displaying images. Each display area 115 comprises a plurality of pixel areas 116 and a spacing area 117 located between any two adjacent pixel areas 116 of the plurality of pixel areas. It should be understood that the image displayed on the display panel is formed by each and every pixel emitting light, and the area where each pixel is located is a pixel area that allows light to pass through (i.e., light-transmissive). The pixel areas 116 can be arranged into an array in rows and columns. There is a spacing area 117 between two adjacent pixel areas. The spacing area 117 is generally opaque. The signal line 110 is located within the spacing area 117. Each pixel area 116 is equipped with a corresponding signal line for controlling the light transmittance of the pixel area 116.

In the embodiment as shown in FIG. 2A, the signal line 110 can be a data line specifically. The data line is used for providing a display signal for pixels. The data line is transmitted to the pixel electrode through an active layer 109 of the driving transistor of the pixel electrode. As shown in FIG. 2A, a pixel electrode 106 is arranged on the substrate 105. A gate insulating layer 107 covers the pixel electrode 106. The active layer 109 and the signal line 110 are formed on the gate insulating layer 107. A passivation layer 111 covers the signal line 110. The material of the passivation layer 111 can be an organic insulating material, such as silicon nitride (SiNₓ). A common electrode 108 is formed on the passivation layer 111.

In the embodiment as shown in FIG. 2B, the signal line 110 can be a gate line specifically. The gate line is used for providing a driving signal for pixels so as to turn on/off the driving transistor that controls the pixel electrodes. As shown in FIG. 2B, pixel electrodes 106 are arranged on the substrate 105, and a portion of pixel electrodes 106 exist in the spacing area 117. The gate line is arranged above the pixel electrode located in the spacing area 117. The gate insulating layer 107 covers the pixel electrode 106 and the gate line. The passivation layer 111 covers the gate insulating layer 107. The common electrode 108 is formed on the passivation layer 111.

The preceding layer structures are all located on the array substrate 101 of the display panel 100. The display panel 100 further comprises an opposite substrate 124. There is a liquid crystal layer 102 between the array substrate 101 and the opposite substrate 124. The opposite substrate 124 also includes a substrate 126 and a back matrix 125 is arranged at a position corresponding to the spacing area 117.

The inventor of the present application pointed out that when the display panel is a liquid crystal panel, the signal line may cause an edge electric field around it, thereby affecting the deflection of liquid crystal molecules and causing a series of problems such as dark state light leakage. Although it is possible to block light leakage by arranging a black mask 125 on the opposite substrate 124, in order to achieve effective blocking, a larger width of the black mask 125 is required, which will affect the transmittance of the display panel. In order to at least solve this problem, as shown in FIGS. 1 to 2B, in the display panel according to the embodiment of the present application, the display panel 100 further comprises an organic film layer 120. The organic film layer 120 is arranged on a side of the signal line 110 away from the substrate 105. Moreover, an orthographic projection of the organic film layer 120 on the substrate 105 covers an orthographic projection of the signal line 110 on the substrate. The term “orthographic projection” should be understood as the projection of the projected target object in a direction perpendicular to a target plane on that target plane. In some embodiments, the material of the organic film layer can have the following characteristics. Firstly, the organic material that forms the organic film layer can be electrically insulated to effectively shield the interference of the signal line. Moreover, the organic material can be photosensitive, enabling the exposed organic material to dissolve in the developing solution, thus eliminating the need for etching processes. Instead, exposure (using a mask with a specific pattern to expose the organic film layer material) and development (cleaning the organic material to remove the exposed area) processes can be directly used to form the desired organic film layer pattern. In addition, the organic material should also have thermosetting properties to fix its shape after exposure and development. In a more specific embodiment, the material of the organic film layer can be resin material, acrylic acid, polyimide, naphthoquinone diazide and other organic materials. In order to effectively shield the electric field, the thickness of the organic film layer can be set to be at least 1.5 μm, for example, from 1.5 μm to 3.0 μm. At this point, the thickness of the organic film layer can effectively shield the electric field of the signal line, but it should not be too thick, resulting in excessive panel segment difference and affecting the surface flatness of the array substrate 101. By arranging an organic film layer at this position, the organic film layer can shield the interference of signal lines on the liquid crystal electric field, reduce the width of light leakage, and bring about various changes that affect the transmittance. For example, from the perspective of pixel design, a decrease in the leakage width allows for an increase in the ratio of the width W of the strip-shaped electrode to the spacing S, and a decrease in the inclination angle of the slit. Moreover, the black mask corresponding to the signal line can be reduced in width, thus resulting in an increase in the opening rate of the panel. Table 1 shows the comparison of parameters between the display panel according to relevant technologies in the art and the display panel according to the embodiment of the present application.

TABLE 1
Comparison of parameters between the display panels

| | | | Panel of the | |
|---|---|---|---|---|
| | | Panel of relevant | present | Transmittance |
| | | technologies | application | proportion |
| Pixel | W/S | 2.6/5.4 | 2.2/4.4 | 3.2%↑ |
| design | inclination | 11° | 7° | |
| | angle of | | | |
| | the slit | | | |
| | Display | ADS | i-ADS | 2%↑ |
| | mode | | | |

| | | | |
|---|---|---|---|
| Opening rate | 62.7% | 71% | 13.24%↑ |
| Gate line black mask | 110 μm | 99 μm | |
| width | | | |
| Data line black mask | 20 μm | 8 μm | |
| width | | | |
| Liquid crystal material | BY19-J02/01A | LCCC-19-1498 | 6%↑ |
| Polarization layer | Anti-glare (AG) | Low | 3%↑ |
| surface treatment | | reflection(LR) | |
| process | | | |
| Comprehensive | 5.1% | 6.5% | 27.5%↑ |
| transmittance | | | |

As shown in Table 1, in these two types of display panels, in terms of pixel design, the ratio of width W to spacing S of the strip-shaped electrode increases, and the inclination angle of the slit decreases. Through this design, the transmittance has been increased by 3.2%. Moreover, the widths of the black masks corresponding to the gate line and the data line are both reduced, resulting in an increase in the opening rate and thus the transmittance. Through these few changes alone, the panel transmittance has been increased by 16.43% (3.2%+13.23%).

In addition, other means can be used to improve the panel transmittance. For example, compared to conventional ADS (Advanced Super Dimension Switch) panels, the embodiment of this application can be applied to i-ADS (inverse Advanced Super Dimension Switch) panels. In the ADS type panel, it includes a block-shaped pixel electrode with a slit and a whole layer of plate-shaped common electrode. The pixel electrode and the common electrode are located on the same side of the liquid crystal layer, and the pixel electrode is closer to the liquid crystal layer than the common electrode. The ADS panel is an advanced panel with a wide viewing angle. In the ADS type panel, a multi-dimensional electric field is formed by the electric field generated by the edge of the slit electrode in the same plane and the electric field generated between the slit electrode layer and the plate-shaped electrode layer, which enables all liquid crystal molecules in the liquid crystal cell to rotate, thereby improving the working efficiency of the liquid crystal and increasing the transmittance efficiency, improving the image quality. Compared to traditional TN type panels, it has advantages such as high resolution, high transmittance, low power consumption, wide viewing angle, high opening rate, low color difference, and no push Mura. However, ADS type panels also have drawbacks in certain aspects. For example, in vertical electric field type liquid crystal display panels such as TN type panels, the liquid crystal molecules are orientated vertically. In this case, even if the array substrate and the opposite substrate are subjected to force and generate optical delay, the vertical electric field type liquid crystal display panel is not prone to light leakage in the dark state. However, in horizontal electric field type liquid crystal display panels such as ADS type panels, the liquid crystal molecules are orientated horizontally. In this case, even if the array substrate and the opposite substrate are subjected to force and generate optical delay, the horizontal electric field type liquid crystal display panel is prone to light leakage in the dark state. Moreover, the opening rate of common ADS panels is still smaller, which cannot meet the demand for high-quality displays. In the i-ADS type panel, it includes a whole layer of a plurality of parallel and spaced strip-shaped common electrodes and block-shaped pixel electrodes, and the pixel electrodes are further away from the liquid crystal layer compared to the common electrodes. In the i-ADS type panel, some of the strip-shaped common electrodes 108 can be arranged in the spacing area 117 between adjacent pixel areas 116, and is located between the signal line 110 (data line) and the liquid crystal layer 102, that is, the common electrode 108 covers the signal line 110 to shield the electric field of the signal line 110 and avoid light leakage problems caused by the presence of the electric field near the signal line 110. However, in conventional i-ADS type panels, the distance between the common electrode and the signal line is relatively close, resulting in a larger coupling capacitance. During the pixel charging and discharging process, it is easy to be pulled by this coupling capacitor, resulting in a decrease in charging rate and poor image quality such as residual images and crosstalk. This problem is particularly severe in large-sized products. In the display panel of the embodiment of the present application, as shown in FIGS. 2A and 2B, the organic film layer 120 can be arranged between the common electrode 108 and the signal line 110, that is, elevated above the signal line 110, increasing the distance between the common electrode 108 and the signal line 110, reducing the coupling capacitance, and facilitating to improve residual images, crosstalk, and other issues. As shown in Table 1, the display panel of the present application combines the i-ADS technology and the organic film layer, improving the panel transmittance. However, the display panel of the present application is not limited to ADS type display panels. It can also be applied to other planar electric field type panels (IPS, In-Plane Switching) and vertical electric field type panels (such as VA, Vertical Alignment) besides ADS.

Besides, by selecting appropriate liquid crystal materials and polarization layer surface treatment processes, the transmittance can also be improved. Overall, the display panel according to the embodiment of the present application has increased the transmittance by 27.5% compared to conventional display panels in the art.

It should be understood that the parameters shown in Table 1 are only intended to indicate that the display panel in the embodiment of the present application has a higher transmittance and the specific reasons for the increase in transmittance. These parameters should not be interpreted as limiting the parameters of the display panel in the embodiment of the present application.

The following describes the materials and dimensions of some layers in the display panel in the embodiment of the present application through examples. In some embodiments, the common electrode 108 can use ITO (indium tin oxide) as the material, with a thickness ranging from 300 Å to 500 Å, such as 400 Å. The pixel electrode 108 can also use ITO as the material, with a thickness ranging from 500 Å to 1000 Å, such as 700 Å. The gate line can use copper as the material, with a thickness ranging from 2000 Å to 5000 Å, such as 3000 Å. The gate insulating layer 107 can use silicon nitride as a material, with a thickness ranging from 3000 Å to 6000 Å, such as 4000 Å. The material of the active layer 109 can be monocrystalline silicon (A-Si), with a thickness ranging from 1000 Å to 3000 Å, such as 2000 Å. The data line can be composed of layers of molybdenum, copper, and molybdenum, with thicknesses of 100 Å-200 Å, 2000 Å-4000 Å, 500 Å-1000 Å, such as 150 Å, 3000 Å, and 800 Å. The passivation layer 111 can use silicon nitride as the material, with a thickness ranging from 500 Å to 6000 Å, such as 1000 Å, 4000 Å, etc.

Due to the arrangement of different layer structures in different areas of the array substrate, the heights at different positions of the array substrate are inconsistent. For example, at the position where an organic film layer 120 is formed, the thickness of the array substrate will increase. In this way, when providing an alignment layer for the array substrate, the alignment layer is not evenly coated on the surface of the array substrate, but rather has segment differences. When using friction rollers to rub the alignment layer, the rollers will experience an uphill and downhill process. For example, when the roller reaches a thicker area, it will experience an uphill, while when it leaves a thicker area, it will experience a downhill. When going downhill, the contact between the roller and the film surface of the alignment layer is weak, resulting in weak alignment force and forming a weak alignment area. The average anchoring energy of liquid crystal molecules in the weak alignment area is relatively weak, making them more susceptible to electric field disturbances and alignment disturbances. Therefore, the leakage of light in the weak alignment area will be more severe and cannot be used as a display area, which actually affects the opening rate. In order to achieve a higher opening rate, it is necessary to reduce the range of the weak alignment area, such as reducing the width of the slope area.

In some embodiments, as shown in FIGS. 2A and 2B, the organic film layer 120 comprises a top area 121 and a side surface 122. The top area 121 is located on a side of the organic film layer 120 away from the signal line 110. The term “top area” can be understood as an area on the film surface of the organic film layer 120 away from the signal line. This area can be a plane or a slightly curved surface, which is basically parallel to the plane where the substrate is located, or only has a small degree of inclination, and its inclination is much smaller than the inclination angle of the side surface 122 relative to the plane where the substrate 105 is located. For example, the inclination angle of the top area 121 relative to the plane where the substrate 105 is located is less than or equal to 5°. The side surface 122 is located between the top area 121 and the signal line 110. The inclination angle α of the side surface 122 relative to the plane where the substrate 105 is located is greater than or equal to 15°. “The inclination angle of the side surface relative to the plane where the substrate is located” can be understood as, in the cross-sectional view of the organic film layer, making a tangent line along the bottom of the side surface, the angle of the tangent line relative to the plane where the substrate is located is namely the inclination angle of the side surface of the organic film layer relative to the plane where the substrate is located. In some more specific embodiments, the inclination angle α of the side surface 122 relative to the plane where the substrate 105 is located can even reach 20° or higher. For example, FIG. 3 schematically illustrates the inclination angle of the side surface of the organic film layer relative to the plane where the substrate is located according to the embodiment of the present application. The figure and its measurement data are obtained from the inventor's photography of the display panel obtained in actual production. Specifically, in FIG. 3, the inclination angle α of the side surface of the organic film layer relative to the plane where the substrate is located is about 22°. In contrast, in conventional display panels, the inclination angle of the side surface of the organic film layer relative to the plane of the substrate is very small, unable to reach 15°, usually only 12° or lower. Therefore, the lateral inclination of the organic film layer 120 in the display panel according to the embodiment of the present application is relatively high, which reduces the width along the direction of the plane where the substrate is located while maintaining the same segment difference, thereby reducing the range of the weak alignment area and helping to improve the opening rate of the panel.

In the display panel of the embodiment of the present application, the organic film layer can be arranged only in the spacing area 117, and can also extend from the spacing area 117 to the pixel area 116. FIG. 4 and FIG. 5 schematically illustrate a partial cross-sectional view of the display panel according to the embodiment of the present application respectively. In the embodiments of FIG. 4 and FIG. 5, the organic film layer 120 extends from the spacing area 117 to the pixel area 116. In this case, the organic film layer 120 comprises a first organic film portion 221 and a second organic film portion 222. The first organic film portion 221 is located in the spacing area 117, and the second organic film portion 222 is located in the pixel area 116. However, the average thickness of the first organic film portion 221 is not the same as the average thickness of the second organic film portion 222. In some embodiments, the average thickness of the first organic film portion 221 is greater than the average thickness of the second organic film portion 222. This is because the second organic film portion 222 is located in the pixel area 116, which may increase the thickness of the pixel area, thereby reducing the effective electric field used to drive the liquid crystal, resulting in a decrease in the deflection voltage of the liquid crystal. By thinning the average thickness of the second organic film portion 222, the thickness of the pixel area can be reduced, the electric field can be increased, and thus the deflection voltage of the liquid crystal can be maintained at a higher level. In addition, thinning the average thickness of the second organic film portion 222 also helps to improve the pixel's heat dissipation ability. In more specific embodiments, the average thickness of the first organic film portion 221 is greater than or equal to 15000 Å, and the average thickness of the second organic film portion 222 is less than or equal to 8000 Å. The specific methods for forming the first organic film portion 221 and the second organic film portion 222 will be described later.

The display panel of the present application can be a large-sized panel, such as a panel with a diagonal size of at least 65 inches. During manufacturing, multiple LCD display panels can be cut from one glass substrate to improve glass utilization efficiency and production efficiency. For example, the size of a glass substrate used as a substrate can reach 2940 mm×3370 mm, which can produce six 75-inch LCD display panels. FIG. 6 schematically illustrates a top view of the substrate. As shown in FIG. 6, the substrate 105 comprises a plurality of display areas 115 thereon, and further comprises a plurality of non-display areas 118 and a cutting area 119 located between any two adjacent non-display areas of the plurality of non-display areas. Each display area 115 in the plurality of display areas is surrounded by a corresponding non-display area 118 in the plurality of non-display areas. That is to say, each display area 115 is surrounded by a non-display area 118, and there is a cutting area 119 between the non-display areas 118. The signal line of the display area 115 may extend to the non-display area 118. The gate driver circuit (also known as GOA circuit, Gate Driver on Array) on the array substrate is also arranged in the non-display area 118. In addition, the sealant used to bond the array substrate 101 and the opposite substrate 124 may also be arranged in the non-display area 118. When dividing a plurality of display areas 115 into separate display panels, the cutting operation is generally carried out within the cutting area 119.

In pursuit of higher production capacity, the automated transportation of substrate continues to accelerate. During the preparation process of display panels, larger glass substrates will experience greater shaking and deformation during the rapid transportation process of the robotic arm compared to smaller glass substrates. The thickness of cutting area 119 and non-display area 118 is usually smaller, so there is a segment difference in the thickness of the display area 115, the non-display area 118, and the cutting area 119, resulting in differences in stress at different positions. FIG. 7 schematically illustrates the stress differences at various positions of the panel. From FIG. 7 it can be seen that the stress at the boundary of the display area 115 is significantly greater than its internal stress, the stress in the non-display area 118 decreases significantly along the direction from the display area 115 to the cutting area 119, while the stress in the cutting area 119 decreases from outside to inside. This is because significant deformation occurs in the cutting area 119 and the non-display area 118, resulting in significant stress. Uneven stress distribution at the edge of the panel can cause panel bending, resulting in light leakage in areas with concentrated stress. FIG. 8 schematically illustrates the light leakage situations of the display panel, where the dotted ellipses circle the positions of the light leakage.

In some embodiments, in order to solve the problem of different stresses at different positions, a segment difference improvement layer 235 can be added in the non-display area 118 to minimize the stress between the display area 115 and the non-display area 118, as shown in FIG. 9A. In some other embodiments, a segment difference improvement layer 235 can be added in the cutting area 119 to reduce the stress between the non-display area 118 and the cutting area 119, as shown in FIG. 9B. However, these solutions need to form additional segment difference improvement layers 235, the coating of which increases production time and reduces production efficiency. In some other embodiments, the organic film layer 120 extends from the display area 115 to the non-display area 118 and the cutting area 119. In this way, there is no need to provide additional segment difference improvement layers to compensate for the segment difference between the display area 115, the non-display area 118, and the cutting area 119, so as to reduce the problem of uneven edge stress caused by shaking and deformation of large-sized substrates during rapid transportation, improve the flatness of the array substrate, and thereby improve the peripheral light leakage of the display panel.

In a more specific embodiment, the organic film layer 120 extending from the display area 115 to the non-display area 118 and the cutting area 119 comprises a first organic film portion 221, a second organic film portion 222, a third organic film portion 241, and a fourth organic film portion 242. The third organic film portion 241 is located in the cutting area 119, and the fourth organic film portion 242 is located in the non-display area 118. The average thickness of the third organic film portion 241 is greater than or equal to the average thickness of the first organic film portion 221, and the average thickness of the third organic film portion 241 is greater than or equal to the average thickness of at least one of the fourth organic film portion 242 and the second organic film portion 222. FIG. 10 schematically illustrates a partial cross-sectional view of the display panel according to the present application. As shown in FIG. 10, generally, only one electrode material layer (such as the material layer of pixel electrode 106 in the embodiment of the present application) and other insulating material layers (such as the material layers of the gate insulating layer 107 and the passivation layer 111) are arranged in the cutting area 119. Therefore, the thickness of the array substrate corresponding to the cutting area 119 is generally the thinnest. The non-display area 118 is also arranged with a conductive material layer that forms the signal line 110, so the thickness of the array substrate corresponding to the non-display area 118 is generally higher than that of the array substrate corresponding to the cutting area 119. There are most layer structures within the display area (including the spacing area and pixel area) which is generally the thickest. Therefore, by making the average thickness of the third organic film portion 241 greater than or equal to the average thickness of the first organic film portion 221, and greater than the average thickness of at least one of the fourth organic film portion 242 and the second organic film portion 222, the thinnest position in the array substrate is supplemented with the thickest organic film layer, thereby improving the segment difference between different areas and reducing the difference in stress between different positions, effectively improving the edge light leakage problem mentioned above.

In the LCD display panel, the sealant 253 is used to connect the array substrate and the opposite substrate. The thickness of the sealant 253 is approximately 25000 Å to 35000 Å, such as 30000 Å. The existing method of applying the sealant relies on controlling the speed and height of the adhesive head to control the amount of adhesive applied at each position, and then achieving rounded corners by assembling and curing. Therefore, the control accuracy of the coating of the rounded corners of the sealant is very difficult, and the monitoring is also quite difficult. For large-sized display panels, due to the large width and length of the sealant, it is more prone to wide deviation and positional accuracy deviation during coating. Especially at corners and other positions, there is often a problem of a large coating deviation due to poor monitoring.

In order to solve the above problem, as shown in FIG. 11, in some embodiments, the portion of the organic film layer located in the non-display area 118, i.e., the fourth organic film portion 242, comprises a groove portion 251 and an edge portion 252 located on both sides of the groove portion 251. The average thickness of the groove portion 251 is less than the average thickness of the edge portion 252. It shows that the fourth organic film portion 242 has a shape of low in the middle and high on both sides. The display panel further comprises sealant 253. In some embodiments, the thickness of the sealant 253 is about 30000 Å. The sealant 253 is located within the groove portion 251. In this way, the sealant 253 can be limited to a predetermined position by the fourth organic film portion 242 during coating, thereby reducing the deviation of the coating position and width. This is particularly important for the coating of sealant at the corners. By limiting the position of the sealant on the fourth organic film portion 242 located in the non-display area 118, it is possible to control the coating accuracy of the sealant.

The above embodiment achieves limiting of the sealant by reducing the local thickness of the organic film layer. In addition to its limiting effect, the thinning of the organic film layer also helps to improve heat dissipation performance. For example, a plurality of transistors may be arranged within each pixel of the display panel, which may emit a large amount of heat during operation. In some embodiments, the thickness of the organic film layer corresponding to the position of the transistor can be reduced to improve heat dissipation performance. For example, in high refresh rate (above 120 Hz) or high-resolution (8k) panels, the transistors connected between the clock signal end and the output end in the shift register unit generate more heat. Therefore, the thickness of the organic film layer can be reduced at the corresponding position of the transistor, which helps with the heat dissipation of the transistor.

In liquid crystal display panels, a photo space (PS) is usually arranged between the array substrate and the opposite substrate to support the two substrates, so as to maintain the distance between them. At the corresponding position of the opposite substrate, a photo space support platform that matches the photo space can be arranged. A conventional LCD display panel can contain two types of photo spaces, namely a main photo space and an auxiliary photo space. The main photo space mainly serves to support the thickness of the cell, therefore, the axial length (i.e. height) of the main photo space is arranged longer, which is greater than the axial length of the auxiliary photo space. The auxiliary photo space mainly plays a role in increasing the compressive capacity of the panel, therefore, the distribution density of the auxiliary photo space can be arranged to be greater than the distribution density of the main photo space. As the height of the photo space increases, it is easy to increase the offset distance between the photo space and the black mask, which reduces the opening rate of the display panel. In the display panel according to the embodiment of the present application, as shown in FIG. 2B, the photo space 150 is located on a side of the organic film layer 120 away from the substrate. In this way, the distance between the array substrate and the opposite substrate will be maintained by the organic film layer 120 and the photo space 150 together, reducing the height of the photo space, reducing the offset distance between the photo space and the black mask, and greatly improving the overall opening rate and transmittance. In a more specific embodiment, the photo space can be arranged on the organic film layer 120 corresponding to the gate line. FIG. 12A schematically illustrates a top view of a display panel according to an embodiment of the present application. As shown in FIG. 12A, the photo space 150 can be arranged in the spacing area 117 of the array substrate. FIG. 12B schematically illustrates a partial cross-sectional view of a relevant display panel. FIG. 12C schematically illustrates a partial cross-sectional view of a display panel according to an embodiment of the present application. The left side of FIG. 12B schematically shows a cross-sectional view of the pixel area, while the right side of FIG. 12B schematically shows a cross-sectional view of the spacing area. In the display panel related to this field, the pixel area of the array substrate includes structures such as pixel electrode 106 and common electrode 108, while the pixel area of the opposite substrate includes structures such as color resistance layer 128 and protection layer 127. The spacing area of the array substrate includes structures such as the material of the pixel electrode 106 and the signal line 110, while the spacing area of the opposite substrate includes structures such as the black mask 125 and the protective layer 127. The photo space 150 is arranged in the spacing area, with a height of from 3 μm to 4 μm. For example, in the panel of FIG. 12B, the height of the photo space reaches 3.16 μm. The display panel of the present application also includes the above structure, and in addition, the spacing area further includes an organic film layer 120. The left side of FIG. 12C schematically shows a cross-sectional view of the pixel area, while the right side of FIG. 12C schematically shows a cross-sectional view of the spacing area. In the display panel according to the embodiment of the present application, the height of the photo space is from 1.4 μm to 2 μm. For example, in the embodiment of FIG. 12C, the height of the photo space can be 1.49 μm. In the display panel of related technologies, the offset distances between the photo space and the black mask of the main photo space and the auxiliary photo space can reach 51.5 μm and 43 μm respectively, while the offset distance between the photo space and the black mask of the display panel according to the embodiment of the present application is 30 μm. Therefore, the display panel of the embodiment of the present application reduces the offset distance between the photo space and the black mask by reducing the height of the photo space, further improving the opening rate of the display panel.

In display panels, the via hole is a means of establishing electrical connections for stacked structures with gaps in between. In the embodiment of the present application, in order to electrically connect the layer structures above and below the organic film layer 120, a via hole 260 is also required in the organic film layer 120. FIG. 13 schematically illustrates a cross-sectional view of a via hole according to an embodiment of the present application. As shown in FIG. 13, the via hole 260 comprises a first opening 261, a second opening 262, and an inner wall 263 located between the first opening 261 and the second opening 262. It can be understood that the first opening 261 is the cross section of the via 260 on one surface of the organic film layer 120, and the second opening 262 is the cross section of the via 260 on the other surface of the organic film layer 120. The inventor believes that the inclination of the inner wall of the via hole should not be too large, otherwise when depositing ITO electrode material into the via hole, it may cause the ITO material to cover the inner wall of the via hole thinly, increasing the contact resistance of the via hole and causing problems such as poor overlap of the via hole. In addition, if the slope of the inner wall of the via hole is large, during the formation of the alignment film, the material of the alignment film will exhibit abnormal diffusion and uneven coating, resulting in defects such as fine horizontal lines and pitting on the screen (i.e. M24 defect). Therefore, it is necessary to reduce the inclination of the inner wall of the via hole. Specifically, the inner wall 263 of the via hole 230 comprises a first inner wall slope gradient zone 2631, a second inner wall slope gradient zone 2632, and an inner wall slope stability zone 2633 between the first inner wall slope gradient zone 2631 and the second inner wall slope gradient zone 2632. The inclination angle of the inner wall slop stability zone 2633 relative to the plane where the substrate is located is less than or equal to 20°. In some more specific embodiments, the inclination angle of the inner wall of the obtained via hole relative to the plane where the substrate is located can be as low as 15°, or even lower, for example, as low as 13°.

This helps to avoid the problem of poor contact of the via hole mentioned above, and also helps with the normal diffusion of the alignment film.

To sum up, the display panel provided in the embodiment of the present application is arranged with an organic film layer on a side of the signal line away from the substrate, which can shield the edge electric field generated by the signal line, reduce the width of the required black mask, and increase the panel opening rate. Moreover, the organic film layer also increases the distance between the common electrode line and the signal line, reduces the capacitance between the two, and improves issues such as crosstalk and residual images. The thickness of the organic film layer arranged in the pixel area is less than that of the organic film layer arranged in the spacing area, maintaining the electric field of the pixel area and maintaining the liquid crystal deflection power supply. In addition, the organic film layer can also be arranged in the non-display area and cutting area to reduce segment differences, improve stress, and reduce light leakage problems caused by stress differences. In addition, by adjusting the thickness of the organic film layer in the non-display area, the limit of the sealant can be achieved.

According to another aspect of the present application, a method of manufacturing a display panel is provided. FIG. 14 schematically illustrates a flowchart of a method of manufacturing a display panel according to an embodiment of the present application. As shown in FIG. 14, the method comprises:
At step S305, providing a substrate, wherein the substrate comprises at least one display area, each display area comprises a plurality of pixel areas and a spacing area located between any two adjacent pixel areas of the plurality of pixel areas;
At step S310, forming a signal line on the substrate, wherein the signal line is located within the spacing area;
At step S315, forming an organic film layer on a side of the signal line away from the substrate, wherein an orthographic projection of the organic film layer on the substrate covers an orthographic projection of the signal line on the substrate.

Next, these steps will be described. Firstly, a substrate is provided. The substrate 105 comprises at least one display area 115, each display area 115 is further divided into a pixel area 116 and a spacing area 117, in which different structures will be formed in subsequent steps. Some layer structures may have already been formed on the substrate 105. For example, on the substrate 105, an ITO material layer may have been formed by methods such as sputtering. The thickness of the ITO material can range from 300 Å to 500 Å, such as 400 Å. Then, the ITO material layer is etched to obtain a pixel electrode 106.

Then, a signal line 110 is formed on the substrate 105, wherein the signal line 110 is located in the spacing area 117. The signal line 110 can comprise at least one of a gate line and a data line, so the steps of forming the signal line 110 include at least one of the steps of forming the gate line and forming the data line. In one embodiment, firstly, a copper layer is formed on the substrate, with a thickness ranging from 2000 Å to 5000 Å, such as 3000 Å. Then, the copper layer is etched to obtain the gate line, which should be located in the spacing area 117 of the substrate. Then, a gate insulating layer 107 can be formed on the gate line, and the material of the gate insulating layer 107 can be silicon nitride, with a thickness of 3000 Å to 5000 Å, such as 4000 Å. Then, an active material layer is further formed on the gate insulating layer 107 through methods such as sputtering and is etched to obtain an active layer 109. The material of the active layer 109 can be monocrystalline silicon, with a thickness ranging from 1000 Å to 3000 Å, such as 2000 Å. Then, a metal material layer is provided on the active layer 109 and is etched to obtain the data line. The data line should also be located in the spacing area 117 of the substrate. The data line can adopt a layered structure of molybdenum, copper, and molybdenum, with thicknesses of 100 Å-200 Å, 2000 Å-4000 Å, 500 Å-1000 Å respectively, such as 150 Å, 3000 Å, and 800 Å. Then, a passivation layer 111 is formed on the data line. The material of the passivation layer can be silicon nitride, with a thickness ranging from 500 Å to 6000 Å, such as 1000 Å, 4000 Å, etc. At the desired position, via holes can be formed in the passivation layer 111 through etching.

Subsequently, an organic film layer 120 is formed on a side of the signal line 110 away from the substrate 105, wherein the orthogonal projection of the organic film layer 120 on the substrate 105 covers the orthogonal projection of the signal line 110 on the substrate 105. Specifically, an organic material layer is coated on the passivation layer 111, and the thickness of the organic material layer can be greater than 15000 Å. Then, the organic material layer is exposed and developed so that the organic film layer exists at least in the spacing area 117, so that the orthogonal projection of the organic film layer on the substrate covers the orthogonal projection of the signal line on the substrate. Organic materials need to have the property that the exposed and developed portion of the organic material will be removed from the organic material layer. Through the above steps, an organic film layer can be provided on the signal line to reduce the edge electric field caused by the signal line.

The step of forming an organic film layer on a side of the signal line away from the substrate will be described in more detail below.

Firstly, an organic material layer is formed on a side of the signal line away from the substrate. Organic materials can be resin materials, acrylic acid, polyimide, naphthoquinone diazide, etc. Organic materials can be coated on the substrate by spin coating. In some embodiments, the thickness of the coated organic film is at least 15000 Å.

In order to make the thickness of the organic film layer in the pixel area smaller than the thickness of the organic film layer in the spacing area, in some embodiments, a halftone mask is used to expose the organic material layer. The halftone mask is provided with zones of different transmittances according to the desired pattern. In this way, the dose of light shining on various parts of the organic material layer varies, and after development, the organic film layer will have different thicknesses in different areas. For example, a halftone mask can include a fully shaded area and a partially transparent area. After exposure and development, the organic material corresponding to the fully shaded area in the organic material layer will not be removed, and this part of the organic material becomes an organic material fully reserved area in the organic material pattern layer. After exposure and development, the organic material corresponding to the partially transparent area will be partially removed, and the remaining part becomes an organic material partially reserved area in the organic material pattern layer. That is to say, the organic material in the organic material fully reserved area has not been removed and is completely reserved. A part of the organic material in the organic material partially reserved area has been removed, and the remaining part of the organic material has been reserved. Therefore, it can be understood that the thickness of the organic material fully reserved area is greater than the thickness of the organic material partially reserved area. After obtaining the organic material pattern layer, the organic material pattern layer can be cured to obtain the organic film layer.

On the halftone mask, the fully shaded area corresponds to the position of the spacing area 117, and the partially transparent area corresponds to the position of the pixel area 116. Therefore, after exposure and development of the organic material layer, the organic material fully reserved area is located in the spacing area 117, and the organic material partially reserved area is located in the pixel area 116, and the thickness of the organic material in the pixel area is less than the thickness of the organic material in the spacing area. In this way, organic film layers with different thicknesses can be formed at different positions through just one exposure. The organic film layer located in the spacing area 117 is thick enough to shield the edge electric field of the signal line, reduce the capacitance between the common electrode and the signal line, and support the photo space 150. The thickness of the organic material located in the pixel area is reduced to a certain extent to maintain the deflection voltage of the liquid crystal within the pixel. Due to this difference in thickness, there is a certain segment difference between the organic material fully reserved area and the organic material partially reserved area.

From the above embodiment it can be understood that for display panels, the segment difference between the organic material fully reserved area and the organic material partially reserved area is very important. However, in conventional techniques, it is difficult to achieve a significant segment difference, mainly because organic materials exhibit significant flow under heating conditions when being cured, resulting in the organic material of the organic material fully reserved area flowing towards the organic material partially reserved area, resulting in a significant reduction in segment difference. In an example, the segment different which was originally greater than 1.5 μm may be reduced to approximately 1.1 μm. In this way, the organic film layer in the spacing area is difficult to shield the edge electric field of the signal line, cannot reduce the capacitance between the signal line and the common electrode, and cannot effectively support the photo space. Correspondingly, the deflection voltage of the liquid crystal of the pixel will also increase, affecting product yield.

After obtaining the organic material pattern layer, the organic material pattern layer can be cured to obtain the organic film layer. In order to reduce the problem of segment difference reduction caused by thermal flow, the present application has improved the process of curing the organic material pattern layer. Specifically, in some embodiments, during the process of curing the organic material pattern layer to obtain the organic film layer, the organic material pattern layer is firstly heated at a first temperature and irradiated with ultraviolet light with a first irradiance to obtain a pre-cured layer, wherein the first temperature is within the range of 120° C. to 140° C., and the first irradiance is within the range of 700 mw/cm² to 1000 mw/cm². This step performs pre-curing to the organic material pattern layer through a combination of low temperature and ultraviolet light irradiation. This step effectively reduces the high-temperature flowability of organic materials and prevents the problem of small segment differences between the organic material fully reserved area and the organic material partially reserved area caused by the high-temperature flowability of the organic materials. Moreover, ultraviolet light ranging from 700 mw/cm² to 1000 mw/cm² can enhance the transmittance of the organic film layer, further improving the transmittance of the finished product. FIG. 15 schematically illustrates the transmittance of the organic film layer to visible light of various wavelengths after being irradiated with different doses of ultraviolet light. As shown in FIG. 15, when the UV irradiation dose reaches 500 mJ, the transmittance of the organic film layer for visible light at all wavelengths can reach 90%, while when the UV irradiation dose reaches 700 mJ, the transmittance of the organic film layer for visible light at all wavelengths can reach 92%. Afterwards, the pre-cured layer is heated at a second temperature to obtain the organic film layer, wherein the second temperature is within the range of 230° C. to 250° C. Through the above two processes, the obtained organic film layer has a large segment difference between the part located in the spacing area and the part located in the pixel area. The organic film layer located in the spacing area can effectively shield the electric field of the signal line, and the organic film layer located in the pixel area does not significantly affect the liquid crystal driving voltage. Moreover, due to the obstruction of thermal flow of organic materials, the slope of the side wall of the part of the organic film layer located in the spacing area is steeper, reducing the width of the weak alignment area and increasing the opening rate of the panel. It should also be pointed out that if only low-temperature baking is used, the time required to achieve the same segment difference is longer (greater than 10 minutes), which is difficult to meet the speed requirements in actual production. If only UV irradiation is used, a significant segment difference (at least 1.5 μm) cannot be obtained. The present application combines low-temperature baking with UV irradiation to achieve better results.

FIG. 16A schematically illustrates the morphological changes of the organic film layer in the conventional method of only using a single high-temperature heating and curing. FIG. 16B illustrates the morphological changes of the organic film layer in the method of manufacturing a display panel according to an embodiment of the present application. As shown in FIG. 16A, in the method of only using a single high-temperature heating and curing, the segment difference of the organic film layer has significantly decreased due to the thermal flow of the organic material. As shown in FIG. 16B, although the degree of segment difference reduction in each of the low-temperature heating with UV irradiation and the high-temperature heating processes is very small, the final segment difference reduction is also smaller than using only the high-temperature heating method.

FIG. 17A schematically illustrates the structural image of the organic film layer obtained by the conventional method of only using a single high-temperature heating and curing. FIG. 17B schematically illustrates the structural image of the organic film layer obtained by the method of manufacturing a display panel according to the embodiment of the present application. From the comparison between FIG. 17A and FIG. 17B, it can be seen that without pre-curing treatment, the thermal flow of the organic material is more severe, the thickness of the organic film layer located above the signal line decreases to 1.6515 μm, the thickness of the organic film layer in the display area increases to 1.0988 μm, and the segment difference is 1.0563 μm. In conventional methods, due to severe thermal flow, the side surface of the organic film layer will be relatively flat, and the inclination angle of this side surface relative to the plane where the substrate is located can generally reach only 12°, and cannot reach 15°. In the method of the present application, after pre-curing, the thermal flow of the organic material is significantly reduced, and the thickness of the organic film layer located above the signal line is maintained at a higher level, reaching 1.7411 μm, the thickness of the organic film layer in the display area remains at a relatively low level, reaching only 0.7366 μm, and the segment difference reaches 1.9172 μm. Moreover, the inclination angle of the side surface of the organic film layer relative to the plane of the substrate can reach more than 15°, or even more than 20°, for example, 22° as shown in FIG. 3. This indicates that the method of the embodiment of the present application embodiment can effectively suppress the thermal flow of organic materials. It should be noted that FIGS. 17A and 17B are images obtained by directly shooting after the organic film layer is made. During the manufacturing process of the display panel, there are other subsequent steps, whether it is the conventional manufacturing process of the display panel or the manufacturing process of the display panel according to the embodiment of the present application, the inclination angle of the side surface of the final display panel will be reduced to a certain extent. However, this does not affect the fact that the inclination angle of the side surface of the organic film layer of the display panel obtained by the method of manufacturing the display panel according to the embodiment of the present application is much greater than that of the side surface of the organic film layer of the conventional display panel.

In some embodiments, the organic film layer 120 extends from the display area 115 to the non-display area 118 and the cutting area 119 to compensate for the segment difference between the display area 115, the non-display area 118, and the cutting area 119, thereby reducing stress unevenness and improving the peripheral light leakage of the display panel. In order to obtain such a display panel, in some embodiments, in the step of exposing and developing the organic material layer to form the organic material layer as an organic material pattern layer, the organic material partially reserved area comprises a first organic material partially reserved area and a second organic material partially reserved area, wherein the organic material fully reserved area is located in the spacing area and the cutting area, the first organic material partially reserved area is located in the non-display area, and the second organic material partially reserved area is located in the pixel area. In this way, organic materials are provided in the display area (including the pixel area and the spacing area), the non-display area, and the cutting area. Moreover, since the organic material fully reserved area is located in the spacing area and the cutting area, that is, the organic film layer in these two areas is the thickest, the organic film layer in the spacing area can effectively shield the electric field of the signal line and reduce the capacitance between the signal line and the common electrode. Moreover, due to the smallest thickness in the cutting area, a thicker organic film layer can more effectively compensate for segment differences, reduce stress, and improve light leakage in the peripheral area of the panel.

In some embodiments, the portion of the organic film layer located in the non-display area 118 comprises a groove portion 251 and an edge portion 252 located on both sides of the groove portion 251. The average thickness of the groove portion 251 is less than the average thickness of the edge portion 252. The sealant 253 of the display panel is located within the groove portion 251. In this way, the sealant 253 can be well stuck in the predetermined position during coating. In order to form such a structure, in some embodiments, by setting the pattern of the halftone mask, the first organic material partially reserved area, after exposure and development, can comprise a groove portion and an edge portion located on both sides of the groove portion, the average thickness of the groove portion is less than the average thickness of the edge portion, wherein the method further comprises providing a sealant in the groove portion. In this way, the first organic material partially reserved area with a groove portion in the non-display area can limit the position of the sealant.

In some embodiments, the organic film layer 120 also needs to be provided with a via hole 260, and the inclination of the inner wall 263 of the via hole should not be too large. Otherwise, when depositing ITO electrode material into the via, it may cause the ITO material to cover the inner wall of the via hole thinly, increasing the contact resistance of the via hole and causing problems such as poor overlap of the via hole. In order to reduce the inclination of the inner wall of the via hole, the embodiment of the present application uses a halftone mask to expose the organic material layer, so that the obtained via hole has a step portion. The presence of the step portion results in a phased decrease in the inner wall of the via, allowing for the use of the high-temperature fluidity of organic materials after high-temperature curing, finally resulting in a lower inclination of the inner wall of the formed via hole.

In the specific method of forming a via hole, firstly, an organic material layer is formed on a side of the signal line away from the substrate. Then, using a halftone mask, the organic material layer is exposed and developed to form the organic material layer as an organic material pattern layer. FIG. 18 schematically illustrates a partial top view of a halftone mask. The halftone mask comprises a fully shaded area 161, a partially transparent area 162, and a fully transparent area 163. The fully transparent area 163 corresponds to the second opening of the via hole. The partially transparent area 162 is a circular area that surrounds the fully transparent area 163. The inner ring of the partially transparent area 162 corresponds to the second opening of the via hole, and the outer ring corresponds to the first opening of the via hole. The fully shaded area 161 surrounds the partially transparent area 162.

FIG. 19 illustrates an example of the exposure process. After exposing and developing the organic material layer using such a halftone mask, the resulting organic material pattern layer will include a via hole pattern. Therefore, the term “via hole pattern” can be understood as a structure obtained from organic materials after exposure and development. It should be noted that the structure has not yet undergone annealing, and during annealing, organic materials may also experience thermal flow, so the via hole pattern is not the final via hole. FIG. 20 schematically illustrates a cross-sectional view of a via hole pattern. The via hole pattern comprises a first opening 261, a second opening 262, and an inner wall pattern 264 located between the first opening and the second opening. The first opening is located on a surface of the organic material pattern layer away from the substrate, the second opening is located on a surface of the organic material pattern layer near the substrate, and the inner wall pattern 264 comprises a first climbing zone 2641, a second climbing zone 2642, and a step portion 2643 located between the first climbing zone 2641 and the second climbing zone 2642, the step portion 2643 is substantially parallel to the first opening 261 and the second opening 262. In some embodiments, the ratio of the distance from the step portion to the first opening to the distance from the step portion to the second opening ranges from 90% to 110%. In this way, the vertical position of the step portion is relatively centered in the via hole, which is conducive to reducing the overall inclination of the inner wall of the via hole.

After obtaining such an organic material pattern layer, the organic material pattern layer is cured to obtain the organic film layer. Curing can be achieved by high-temperature heating, such as in an environment between 230° C. and 250° C., to utilize the high-temperature fluidity of organic materials, resulting in the fusion of the first climbing zone 2641, the second climbing zone 2642, and the step portion 2643, making the inner wall of the finally formed via hole smoother and further forming a via hole with an inner wall of lower inclination. After being manufactured by the above method in the present application, the inner wall of the obtained via hole is very flat, and its inclination degree is very small, which can be less than 20°, or even as low as 15° or lower, for example, as low as 13°. In the conventional method of manufacturing the via hole, the slope of the inner wall of the via hole is generally 40°, with a minimum of 30°, which cannot reach the degree of 20° or lower in the embodiment of the present application.

In summary, the method of manufacturing a display panel according to the embodiment of the present application can be used to obtain a display panel according to the embodiment of the present application, which has all the characteristics mentioned earlier. Moreover, the method of the present application adopts a pre-curing method to reduce the high-temperature flowability of organic materials and prevent the problem of reduced segment difference of organic film layers with different thicknesses due to high-temperature flowability. Moreover, when using a halftone mask to manufacture the via hole, the inner wall of the obtained via hole has a smaller degree of inclination.

As those skilled in the art will understand, although the various steps of the method in the embodiment of this disclosure are described in a specific order in the accompanying drawings, this does not require or imply that these steps must be executed in that specific order, unless otherwise explicitly stated in the context. Additionally or alternatively, multiple steps can be merged into one step for execution, and/or one step can be decomposed into multiple steps for execution. In addition, other method steps can be inserted between the steps. The inserted steps can represent improvements to methods such as that described herein, or they can be independent of the method. Furthermore, the given step may not have been fully completed before the next step begins.

In the description of the embodiments of this disclosure, the terms “up”, “down”, “left”, “right” and other indications of orientation or positional relationships are based on the orientation or positional relationships shown in the accompanying drawings, only for the convenience of describing the embodiments of this disclosure and not requiring them to be constructed and operated in a specific orientation. Therefore, it cannot be understood as a limitation of this disclosure.

In the description of this specification, the reference terms “one embodiment”, “another embodiment”, etc. refer to the specific features, structures, materials, or characteristics described in conjunction with the embodiment being included in at least one embodiment of this disclosure. In this specification, the schematic expressions of the above terms do not necessarily refer to the same embodiments or examples. Moreover, the specific features, structures, materials, or characteristics described can be combined in an appropriate manner in any one or more embodiments or examples. In addition, those skilled in the art can combine the different embodiments or examples described in this specification and the features of different embodiments or examples without mutual contradiction. Furthermore, it should be noted that in this specification, the terms “first” and “second” are only used for descriptive purposes and cannot be understood as indicating or implying relative importance or implying the quantity of technical features indicated.

The above is only the specific implementation of this disclosure, but the protection scope of this disclosure is not limited to this. Any changes or replacements that can be easily conceived by those skilled in the art within the technical scope disclosed herein should be covered within the protection scope of this disclosure. Therefore, the protection scope of this disclosure should be subject to the protection scope of the claims.

1. A display panel, comprising a substrate and a signal line arranged on the substrate, wherein the substrate comprises at least one display area, each display area comprises a plurality of pixel areas and a spacing area located between any two adjacent pixel areas of the plurality of pixel areas, the signal line is located within the spacing area,
wherein the display panel further comprises an organic film layer, the organic film layer is arranged on a side of the signal line away from the substrate, and an orthographic projection of the organic film layer on the substrate covers an orthographic projection of the signal line on the substrate.

2. The display panel as claimed in claim 1, wherein the organic film layer comprises a top area and a side surface, the top area is located on a side of the organic film layer away from the signal line, and the side surface is located between the top area and the signal line,
wherein an inclination angle of the side surface relative to a plane where the substrate is located is greater than or equal to 15°.

3. The display panel as claimed in claim 1, wherein the organic film layer extends from the spacing area to the pixel area, wherein the organic film layer comprises a first organic film portion and a second organic film portion, the first organic film portion is located in the spacing area, and the second organic film portion is located in the pixel area, wherein an average thickness of the first organic film portion is greater than an average thickness of the second organic film portion.

4. The display panel as claimed in claim 3, wherein the average thickness of the first organic film portion is greater than or equal to 15000 Å.

5. The display panel as claimed in claim 3, wherein the average thickness of the second organic film portion is less than or equal to 8000 Å.

6. The display panel as claimed in claim 1, further comprising a common electrode layer, the common electrode layer comprising a plurality of parallel and spaced strip-shaped common electrodes, wherein some of the plurality of strip-shaped common electrodes are arranged in the spacing area, and the organic film layer is located between the strip-shaped common electrodes that are arranged in the spacing area and the signal line.

7. The display panel as claimed in claim 1, wherein the at least one display area comprises a plurality of display areas, the substrate further comprises a plurality of non-display areas, each of the plurality of non-display areas surrounds a corresponding display area of the plurality of display areas, the substrate further comprises a cutting area located between any two adjacent non-display areas of the plurality of non-display areas,
wherein the organic film layer extends from the display area to the non-display area and the cutting area.

8. The display panel as claimed in claim 7, wherein the organic film layer comprises a first organic film portion, a second organic film portion, a third organic film portion and a fourth organic film portion, the first organic film portion is located in the spacing area, the second organic film portion is located in the pixel area, the third organic film portion is located in the cutting area, the fourth organic film portion is located in the non-display area, wherein an average thickness of the third organic film portion is greater than or equal to an average thickness of the first organic film portion, and the average thickness of the third organic film portion is greater than an average thickness of at least one of the second organic film portion and the fourth organic film portion.

9. The display panel as claimed in claim 8, wherein the fourth organic film portion comprises a groove portion and an edge portion located on both sides of the groove portion, an average thickness of the groove portion is less than an average thickness of the edge portion,
wherein the display panel further comprises a sealant, which is located in the groove portion.

10. The display panel as claimed in claim 1, further comprising a photo space, wherein the photo space is located on a side of the organic film layer away from the substrate.

11. The display panel as claimed in claim 1, wherein the organic film layer comprises a via hole, the via hole comprises a first opening, a second opening, and an inner wall located between the first opening and the second opening, the inner wall comprises a first inner wall slope gradient zone, a second inner wall slope gradient zone, and an inner wall slope stability zone between the first inner wall slope gradient zone and the second inner wall slope gradient zone, wherein an inclination angle of the inner wall slop stability zone relative to the plane where the substrate is located is less than or equal to 20°.

12. A method of manufacturing a display panel, comprising:
providing a substrate, wherein the substrate comprises at least one display area, each display area comprises a plurality of pixel areas and a spacing area located between any two adjacent pixel areas of the plurality of pixel areas;
forming a signal line on the substrate, wherein the signal line is located within the spacing area;
forming an organic film layer on a side of the signal line away from the substrate, wherein an orthographic projection of the organic film layer on the substrate covers an orthographic projection of the signal line on the substrate.

13. The method as claimed in claim 12, wherein forming an organic film layer on a side of the signal line away from the substrate comprises:
forming an organic material layer on a side of the signal line way from the substrate;
exposing and developing the organic material layer using a halftone mask so as to form the organic material layer as an organic material pattern layer, wherein the organic material pattern layer comprises an organic material fully reserved area and an organic material partially reserved area, the organic material fully reserved area is located in the spacing area, the organic material partially reserved area is located in the pixel area, wherein a thickness of the organic material fully reserved area is greater than a thickness of the organic material partially reserved area;
curing the organic material pattern layer so as to obtain the organic film layer.

14. The method as claimed in claim 13, wherein curing the organic material pattern layer so as to obtain the organic film layer comprises:
heating at a first temperature and irradiating the organic material pattern layer with ultraviolet light with a first irradiance to obtain a pre-cured layer, wherein the first temperature is within a range of 120° C. to 140° C., and the first irradiance is within a range of 700 mw/cm²-1000 mw/cm²; and
heating the pre-cured layer at a second temperature so as to obtain the organic film layer, wherein the second temperature is within a range of 230° C. to 250° C.

15. The method as claimed in claim 13, wherein the at least one display area comprises a plurality of display areas, the substrate further comprises a plurality of non-display areas, each of the plurality of non-display areas surrounds a corresponding display area of the plurality of display areas, the substrate further comprises a cutting area located between any two adjacent non-display areas of the plurality of non-display areas,
wherein in the step of exposing and developing the organic material layer using a halftone mask so as to form the organic material layer as an organic material pattern layer, the organic material partially reserved area comprises a first organic material partially reserved area and a second organic material partially reserved area, wherein the organic material fully reserved area is located in the spacing area and the cutting area, the first organic material partially reserved area is located in the non-display area, and the second organic material partially reserved area is located in the pixel area.

16. The method as claimed in claim 15, wherein the first organic material partially reserved area comprises a groove portion and an edge portion located on both sides of the groove portion, an average thickness of the groove portion is less than an average thickness of the edge portion, wherein the method further comprises:
providing a sealant in the groove portion.

17. The method as claimed in claim 12, wherein the organic film layer comprises a via hole, and forming an organic film layer on a side of the signal line away from the substrate comprises:
forming an organic material layer on a side of the signal line way from the substrate;
exposing and developing the organic material layer using a halftone mask so as to form the organic material layer as an organic material pattern layer, wherein the organic material pattern layer comprises a via hole pattern, which comprises a first opening, a second opening, and an inner wall pattern located between the first opening and the second opening, the first opening is located on a surface of the organic material pattern layer away from the substrate, the second opening is located on a surface of the organic pattern layer near the substrate, the inner wall pattern comprises a first climbing zone, a second climbing zone, and a step portion located between the first climbing zone and the second climbing zone, the step portion is parallel to the first opening and the second opening;
curing the organic material pattern layer so as to obtain the organic film layer.

18. The method as claimed in claim 17, wherein a ratio of a distance from the step portion to the first opening to a distance from the step portion to the second opening is within a range of 90%-110%.
